(19) United States
(12) Patent Application Publication
(10) Pub. No.: US 2004/0262721 A1
(43) Pub. Date: Dec. 30, 2004

(54) Manufacturing method for power semiconductor electronic devices

(75) Inventors: Claudio Deodato, Cologno Monzese (IT); Roberto Tiziani, Nerviano (IT)

Correspondence Address: JENKENS & GILCHRIST, PC, 1445 ROSS AVENUE, SUITE 3200, DALLAS, TX, 75202, US

(73) Assignee: STMicroelectronics S.r.I., Agrate Brianza (IT)

(21) Appl. No.: 10/833,883

(22) Filed: Apr. 27, 2004

(30) Foreign Application Priority Data
Apr. 30, 2003 (EP) 03425281.7

(51) Int. Cl. H01L 21/48; H01L 23/495

(52) U.S. Cl. 257/676; 438/123

(57) ABSTRACT

A planar metallic foil is formed defining a lie plane which includes a supporting frame for a mount pad and corresponding leads being short-circuited to the mount pad. The mount pad is then down-set on a plane being parallel to the lie plane so as to keep at least a group of leads on the lie plane and separate by shearing the mount plane from the group of leads. A die is then mounted on a first surface of the mount pad. Electrical connections are then formed between the die and the group of leads. The frame is then encapsulated in a protective package so as to leave a second surface of the mount pad, being opposite to the first surface, exposed from the protective package.

### PRIORITY CLAIM

The present application claims priority from European Application for Patent No. 03425281.7 filed Apr. 30, 2003, the disclosure of which is hereby incorporated by reference.

### BACKGROUND OF THE INVENTION

1. Technical Field of the Invention

The present invention relates to a manufacturing method for power semiconductor electronic devices encapsulated in a protective package. More specifically, the invention relates to a method for manufacturing power semiconductor electronic devices. The invention also relates to a method for manufacturing frames for semiconductor electronic devices. The invention still further relates to a frame for power electronic devices.

2. Description of Related Art

As is well known, semiconductor electronic devices comprise an electronic circuit manufactured in a semiconductor material chip, a so-called “die”, with a surface of a few square millimeters. Traditionally, the electronic circuit is monolithically integrated in the die. The die, for being thermally and mechanically protected, is thus coated with a casing or package.

These devices require, for their electrical connection to an external circuit, suitable support and electrical interconnection means. To this purpose, a conductive leadframe is used, which is composed of a thin wrought metallic plate comprising a die mount pad, also called a die pad, which is substantially rectangular, whereon the die and a plurality of narrow strips are fixed and insulated from the mount pad, representing electrical connectors or leads.

The plurality of narrow strips have an end electrically connected to the integrated circuit, through wires welded between each end and corresponding integrated circuit pads, while the opposite free end of the electrical connectors projects outside the package to form the so-called electrical interconnection pins of the device.

In the case of power electronic devices (i.e., devices being capable of producing a relatively high amount of heat), reference is commonly made to so-called power packages. This term means a device being capable of dissipating heat.

A first solution to transfer outside the heat produced during the integrated circuit operation is to couple the frame, for example of a single-thickness material, to a heat-sink element. The heat-sink element is simply a metallic element, for example, a flattened cylinder or parallelepiped-shaped heat conductor, with a mass being considerably higher than the die (the electronic device) and which is fixed to the frame by riveting or welding.

Traditionally, in a power package, the heat-sink element has a heat-sink element surface being exposed from the package while the opposite larger surface and all side surfaces are insulated (for example, coated with the package plastic material).

Although advantageous under many aspects, this first solution has several drawbacks. In fact, to perform the riveting or welding it is necessary to insert some mechanical steps in the power package manufacturing process involving a considerable increase in the final device costs.

A second solution to increase the frame thickness in correspondence of the portion being exposed from the package. This implies the use of a double-thickness material to manufacture the frame. In particular, the frame is formed by a metallic plate comprising a first portion of a first thickness equal to the final thickness of the portion being exposed from the package, and a second portion of a second thickness equal to the lead final thickness. This second reduced-thickness portion is obtained by milling the starting metallic plate.

This solution also has some drawbacks. In fact, this solution involves a considerable material waste and a series of additional operations in the manufacturing process which increase the difficulty and the corresponding costs.

A further solution for manufacturing a power semiconductor electronic device 1a is shown in FIGS. 1 to 4 and it implies the use of a non-planar frame 2a. This frame has a mount pad 3a being downset with respect to the plane on which leads 4a lie. The frame 2a also comprises arms or braces 5a to physically support the mount pad 3a.

This downsetting is obtained by simply deforming the plane metal foil wherein the mount pad 3a and leads 4a are manufactured. These leads 4a, are physically separated from the mount pad 3a through a size opening 4b formed in the plane metallic foil as shown in FIGS. 3 and 4. After mounting the die on the mount pad 3a, the so-obtained frame 3a is encapsulated in a plastic package 6a so as to leave a surface of the mount pad 3a exposed from the plastic package 6a.

This solution also has some drawbacks. In fact, there are some very strict design rules to correctly engrave the metallic foil wherein the mount pad 3a and the leads 4a of the frame 2a are formed. In particular, it is impossible to open the foil openings 4b whose size A is smaller than the thickness of the foil itself. Therefore, the minimum distance which must exist in traditional frames 2a between the mount pad 3a and leads 4a is equal to the size A. Although this manufacturing technique is low-cost, the mount pad 3a size is limited by these design rules.

There accordingly continues to exist a need in the art for providing a manufacturing method for power semiconductor electronic devices encapsulated in a protective package which allows a large sized die to be located in the protective package without increasing traditional manufacturing process costs.

### SUMMARY OF THE INVENTION

In accordance with one aspect of the present invention, the frame is modified so that leads are initially short-circuited to the mount pad in order to increase the size of the pad itself. The physical separation between the leads and the mount pad is performed in the downsetting step of the mount pad with respect to the leads. This downsetting is performed by shearing the metallic foil between the leads and the mount pad.

Thus, the present invention relates to a frame for power electronic devices which comprises:

a plurality of leads located on a first plane, and

a mount pad downset with respect to said first plane and comprised in a second plane.

An aspect of the present invention concerns a frame for electronic devices. The frame includes a plurality of leads located on a lie plane, and a mount pad being downset with respect to said lie plane and comprised in a plane being parallel to said lie plane, wherein an inner wire portion of said leads is substantially aligned along the vertical of an external wire portion of said mount pad.

Another aspect of the present invention concerns a method for manufacturing a leadframe. Conductive foil is patterned in a first plane to define a mounting pad area and a plurality of conductive leads which are short circuited to the mounting pad area. The mounting pad area is then downset to a second plane offset from the first plane. At least some of the plurality of conductive leads are then detached from the mounting pad area.

Another aspect of the present invention concerns a leadframe made from conductive foil patterned to define a mounting pad area and a plurality of conductive leads. Some of the conductive leads are short circuited to the mounting pad area, while others of the conductive leads are sheared from the mounting pad area. The mounting pad area is downset in a first plane which is vertically offset from a second plane in which all the conductive leads substantially lie.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 is a view from above of a power package manufactured according to the prior art;

FIG. 2 is a side view of a frame used in the power package of FIG. 1;

FIGS. 3 and 4 are sectional views along the line I-I of the frame used during the manufacturing process of the power package of FIG. 1;

FIG. 5 is an exploded view from above of a power package manufactured according to the invention;

FIG. 6 is a side view of a frame used in the power package of FIG. 5;

FIGS. 7 and 8 are sectional views along the line II-II of the frame used during the manufacturing process of the power package of FIG. 5;

FIGS. 9 and 10 are views from above of an alternative embodiment of a power package manufactured according to the invention during manufacturing steps;

FIG. 11 is a side view of a frame used in the power package of FIG. 10;

FIG. 12 is a photographic representation of the frame of FIG. 11.

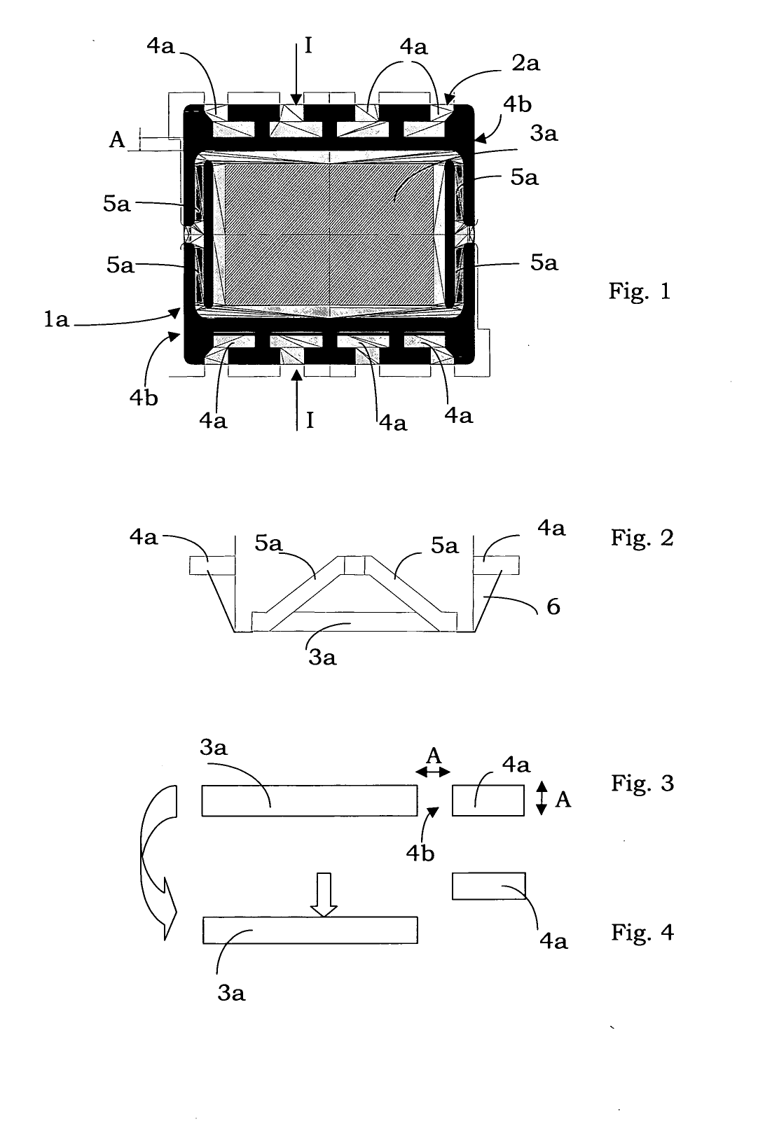

### DETAILED DESCRIPTION OF THE DRAWINGS

The invention particularly relates, but not exclusively, to a method for manufacturing power containers for power semiconductor electronic devices. However, the following description is made with reference to this field of application for convenience of illustration only.

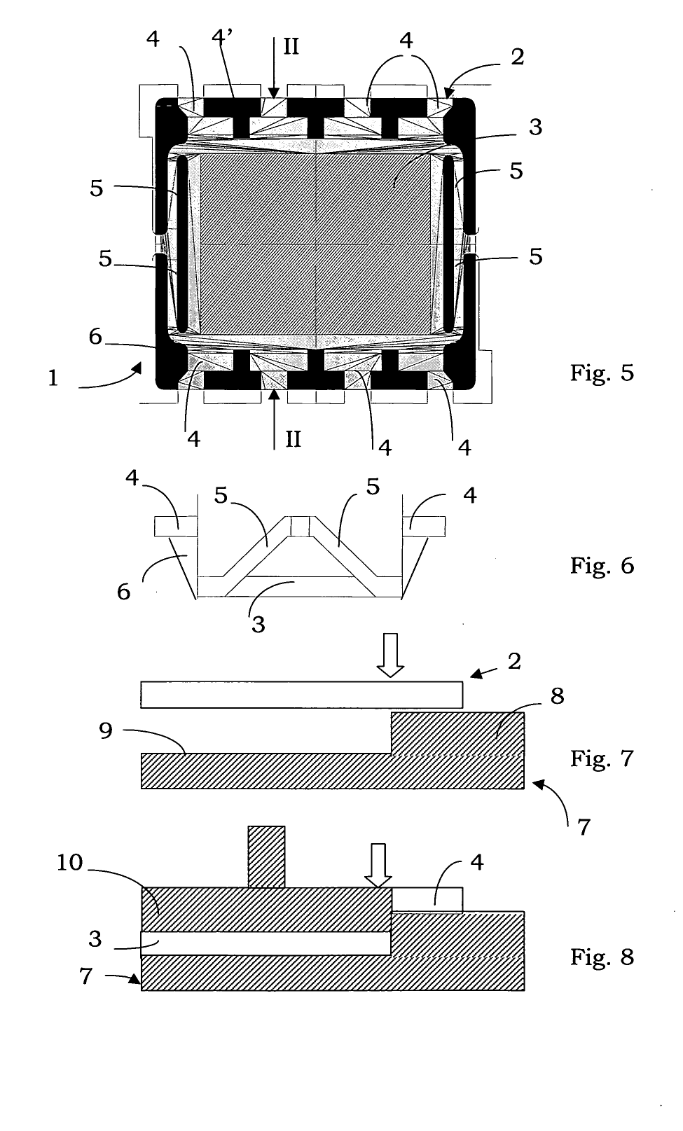

With reference to FIGS. 5 to 8, a method for manufacturing semiconductor electronic devices encapsulated in a protective package is described.

In particular, with reference to FIG. 5, an electronic power device 1 is shown, which comprises a frame 2 being partially encapsulated in an insulating protective package 6, for example of plastic material. This frame 2 comprises a mount pad 3 whereon a die comprising an integrated circuit and a plurality of leads 4 are fixed, which are electric connectors of the electronic device 1 and of the arms 5 to physically support the mount pad 3.

According to an aspect of the invention, the frame 2 is formed in a planar conductive foil defining a lie plane, for example metallic, wherein the plurality of leads 4 are formed, which are at first physically connected to a mount pad 3 as shown in FIG. 5.

Leads are separated from each other by openings 4′ formed in the planar conductive foil.

The mount pad 3 is thus separated by means of the method according to an aspect of the invention from the leads 4 and downset on a parallel plane to the lie plane wherein leads 4 lie. Arms 5 ensure the physical support of the mount pad 3.

Advantageously, in the electronic device 1 manufactured according to this aspect of the invention, the external wire of the mount pad 3 is substantially aligned along the vertical of the lead 4 inner wire as shown in FIG. 6.

A method for manufacturing semiconductor electronic devices 1 according to an aspect of the invention is now described in detail.

In the method according to the aspect of the invention, a frame 2 is formed, in a planar conductive foil defining a lie plane, comprising a substantially rectangle-shaped mount pad 2 and a plurality of leads 4 laterally projecting from the mount pad 2. Leads 4 are thus short-circuited to the mount pad 2.

The planar conductive foil now rests on a matrix 7 equipped with a peripheral portion 8 being elevated with respect to a central portion 9. The central portion 9 has substantially the same dimension as the mount pad 3.

A punch 10 having substantially the same size as the central portion 9 abuts against the plane conductive foil in correspondence with the central portion 9. A pressure is thus exerted on the punch 10 so that the mount pad 3 is separated by shearing from the frame 2 portion comprising the leads 4 abutting thus against the matrix central portion 9 as shown in FIG. 8.

The frame 2 resulting therefrom is no longer planar, but the mount pad 3 thereof is downset on a plane being parallel to the lie plane whereon leads 4 lie.

It results therefore that the internal wire of the leads 4 is substantially aligned along the vertical of the external wire of the mount pad 3.

The process for manufacturing semiconductor electronic devices then continues with the conventional process steps of:

mounting a die on a surface of the mount pad 3,

forming the electrical connections between the die and the leads 4, and

encapsulating the frame 2 in a plastic package 6 so as to leave the second surface of said mount pad 3 being opposite to the first surface exposed from the plastic package 6.

Although illustrated with a frame 2 wherein the leads are only on two sides, aspects of the present invention can be advantageously used also for frames having the leads or a group of leads only on one side or on four sides.

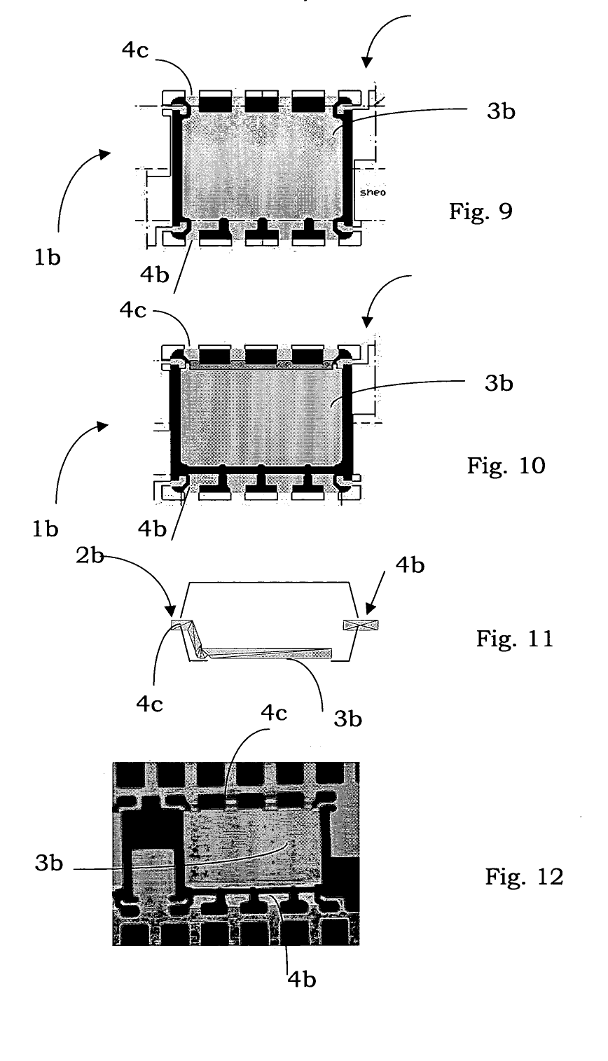

In particular, with reference to FIGS. 9 to 12, a method for manufacturing electronic devices is described. A supporting frame 2b is formed in a planar conductive foil defining a lie plane, comprising a substantially rectangle-shaped mount pad 2b and two groups of leads 4b, 4c laterally projecting on opposite sides of the mount pad 2b. Leads 4b, 4c are thus short-circuited to the mount pad 2b as shown in FIG. 9.

The planar conductive foil thus rests on a matrix equipped with a peripheral portion being elevated with respect to a central portion.

A punch abuts against the plane conductive foil in correspondence with the central portion. A pressure is thus exerted on the punch so that the mount pad 3 is separated by shearing only from a first group of leads 4b.

On the contrary, the mount pad 3 is connected to the second group of leads 4c, and in downsetting with respect to the first group of leads 4b it shifts towards this second group of leads 4c as shown in FIGS. 10 and 11.

The frame 2b resulting therefrom is no longer planar, but the mount pad 3b thereof is downset on a plane being parallel to the lie plane whereon leads 4b and 4c lie.

The process for manufacturing semiconductor electronic devices thus continues with the traditional process steps of mounting the die on the frame, of electrically connecting the leads 4b to the die and of encapsulating the frame 2b in a plastic package 6b.

Advantageously, in this embodiment, the mount pad 4b is still short-circuited to the second group of leads 4c, after the downsetting step. This second group of leads 4c can thus be used for connecting the mount pad 4b to ground.

In conclusion, if using the same frame 2, 2b as in the traditional downsetting technique, the mount pad 3, 3b according to the invention is larger than prior art pads 3a since the leads 4, 4b, effective to form the die electrical connection, are not physically separated from the mount pad 3 before downsetting.

In fact, in traditional manufacturing processes leads 4a are separated from the mount pad 3a before downsetting and the mount pad 3a is downset only by deforming the planar metallic foil.

With the method according to aspects of the invention, the mount pad 3, 3b is separated by shearing from leads 4, 4b and thus downset in a single operation.

Therefore this foil portion, which was eliminated in the prior art, is advantageously used in the device 1 according to the invention, to enlarge the mount pad 3, 3b.

It is therefore available, for the final device 1, both a larger mount surface and a larger exposed portion for the integrated circuit cooling.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A method for manufacturing a semiconductor electronic device, comprising:
forming, from a planar metallic foil defining a lie plane, a supporting frame comprising a mount pad for said device and corresponding leads being short-circuited to said mount pad;
downsetting said mount pad on a plane being parallel to said lie plane while keeping said leads on said lie plane and separating by shearing said mount plane from at least a group of leads;
mounting a die on a first surface of said mount pad;
forming the electrical connections between said die and said at least one group of leads; and
encapsulating said frame in a protective package so as to leave a second surface of said mount pad, being opposite to said first surface, exposed from said protective package.

2. The method according to claim 1, wherein downsetting of said mount pad comprises:
resting said planar foil on a matrix comprising a central portion located in said lie plane and a peripheral portion having an upper surface located in said parallel plane;
abutting a punch aving substantially the same size as said mount portion on said foil in correspondence with said central portion; and
exerting a pressure on the punch so as to separate by shearing the foil, leaving the leads in said lie plane and bringing said mount pad on said parallel plane.

3. A method for manufacturing a leadframe for a semiconductor product comprising:
manufacturing a supporting frame comprising a mount pad and respective leads being short-circuited to said mount pad on a lie plane;
downsetting said mount pad on a plane being parallel to the lie plane;
separating at least one group of said leads by shearing from said mount pad.

4. A frame for electronic devices comprising:
a plurality of leads located on a lie plane,
a mount pad being downset with respect to said lie plane and comprised in a plane being parallel to said lie plane, wherein an inner wire portion of said leads is substantially aligned along the vertical of an external wire portion of said mount pad.

5. The frame according to claim 4, wherein the mount pad is substantially rectangular.

6. The frame according to claim 4, wherein said group of leads is formed on at least two opposite sides of said frame.

7. The frame according to claim 4, wherein said group of leads is formed on four sides of said frame.

8. An electronic device, comprising:
a supporting frame comprising a mount pad and respective leads initially being short-circuited to said mount pad on a lie plane;
wherein the mount pad is then downset during manufacture to a plane being parallel to the lie plane; and
wherein at least one group of said leads is separated during manufacture by shearing from said mount pad.

9. The electronic device of claim 8, wherein the at lead one group of said leads is sheared during the manufacturing operation to downset the mount pad.

10. A leadframe manufacturing method, comprising:
patterning conductive foil in a first plane to define a mounting pad area and a plurality of conductive leads which are short circuited to the mounting pad area;
downsetting the mounting pad area to a second plane offset from the first plane; and
detaching at least some of the plurality of conductive leads from the mounting pad area.

11. The method of claim 10, wherein detaching comprises a shearing that is performed by the downsetting operation.

12. The method of claim 10, wherein downsetting comprises punching mounting pad area.

13. A leadframe, comprising:
conductive foil patterned to define a mounting pad area and a plurality of conductive leads, some of the conductive leads being short circuited to the mounting pad area, others of the conductive leads being sheared from the mounting pad area, the mounting pad area further being downset in a first plane which is vertically offset from a second plane in which all the conductive leads substantially lie.
